(19) United States
(12) Patent Application Publication
(10) Pub. No.: US 2021/0305810 A1
(43) Pub. Date: Sep. 30, 2021

(54) SITE-TO-GRID POWER INTERFACE OPTIMIZER

(71) Applicant: INFINITE INVENTION INC., Falls Church, VA (US)

(72) Inventor: Whitman Fulton, Falls Church, VA (US)

(21) Appl. No.: 17/100,231

(22) Filed: Nov. 20, 2020

Related U.S. Application Data
(60) Provisional application No. 62/904,798, filed on Sep. 24, 2019.

(51) Int. Cl. H02J 3/00; G01R 22/06

(52) U.S. Cl. CPC H02J 3/001; G01R 22/063

(57) ABSTRACT

On a circuit between the electric grid and the site-side (below-meter) electric network an interconnection point for weatherized energy storage, combined with a disconnect switch on the grid to site circuit that, when opened, isolates the site and the energy storage below the circuit from the grid, a computing system containing metering, communications, and processing, for the grid to site circuit, and a data connection to a connected energy storage system to manage its operation in response to signals from the computing system.

### BACKGROUND

Electrical energy storage is falling in cost and increasing in deployment. Electrical energy storage provides grid stability, generation cost reduction; and, when installed on-site with electrical loads, the storage keep those loads powered during grid outages.

Among the problems limiting the deployment of the technology are the typical site side (below meter) point of interconnection point and the associated wiring costs and National Electrical Code rules. Current market technology requires moderate temperature ranges to function properly and often must be installed in a weatherized environment. Site-level outage ride-through requires the installation of dedicated circuits and switchgear. Deployments are often poorly correlated with grid locational value. Costs and ownership models limit deployment of energy storage to those sites that can afford it.

FIG. 1 illustrates a prior art arrangement illustrating how a utility's distribution system may be connected to the private distribution system of a customer who receives two-phase service (such as a residential customer with 110-volts/220-volt service or a small business owner with 110-volt/220-volt service).

A utility substation 20 receives power at a high voltage from a generating station (not pictured) and distributes this power, at a stepped-down but nevertheless relatively high voltage and in three phrases, to a network that includes a step-down transformer 22. The primary winding of the transformer 22 receives one of the phases from the substation 20, and the secondary winding is center-tapped. The center tap, which is grounded, is connected to a neutral power line 24. A “leg 1” of the secondary winding is connected to a leg-1 power line 26 and a “leg 2” of the secondary winding is connected to a leg-2 power line 28. The potential difference between the leg-1 power line 26 and the neutral line 24 is typically 110 volts (average) and the potential difference between the leg-2 power line 28 and is also typically 110 volts (average). However, leg-1 power line 26 is 180° out of phase with the leg-2 power line 28. Consequently, a load which is connected between the neutral line 24 and either of the leg-1 or leg-2 power lines 26 and 28 receives 110 volts while a load connected between the leg-1 and leg-2 power lines 26 and 28 receives 220 volts. The two-phase service that is illustrated in FIG. 1 can thus supply power to both 110 volt loads and 220 volt loads that are connected to a customer's private distribution system.

FIG. 1 also shows the front side of a meter socket box 30 and the back side of a watt-hour meter 32. The meter socket box 30 has a recessed socket 34 with utility-side contacts 36 and 38 and customer-side contacts 40 and 42. Each of the contacts includes a pair of electrically conductive arms (not numbered). The socket 34 also includes a neutral contact 44 that is connected by a neutral service line 46 to the neutral power line 24 and to a neutral line 48 of the customer's private distribution system. The arms of the contact 36 are connected via a leg-1 service line 50 to the leg-1 power line 26 and the arms of the contact 38 are connected via a leg-2 service line 52 to the leg-2 power line 28. The arms of the contact 40 are connected to a leg-1 line 54 of the customer's distribution system while the arms of the contact 42 are connected to leg-2 line 56 of the customer's distribution system.

The back side of the meter 32 is provided with four contacts, 58, 60, 62, and 64. When the meter 32 is plugged into the socket 34 as indicated schematically by arrow 66, the contact 60 is wedged between the arms of the contact 36 to form a connection, the contact 58 is wedged between the arms of the contact 38 to form a connection, the contact 64 is wedged between the arms of the contact 40 to form a connection, and the contact 62 is wedged between the arms of the contact 42 to form a connection. Meter 32 is an electromechanical meter having a Farraday motor and a gear train (not illustrated) which turns dials (not illustrated) when the motor rotates. The meter includes a low resistance winding (not numbered) between the contacts 58 and 62 and another low resistance winding (also not numbered) between the contacts 60 and 64 The meter also includes a high resistance winding (not numbered) between the contacts 62 and 64. The net result is that, when the meter 32 is plugged into the socket 34, the leg-1 line 54 of the customer's distribution system is connected to leg-1 power line 26, the neutral line 48 of the customer's distribution system is connected to neutral power line 24, and the leg-2 line 56 of the customer's distribution system is connected to the leg-2 power line 28. The meter 32 records the watt-hours consumed by the loads connected to the customer's distribution system.

FIG. 2 shows an overview of a customer site-side (below meter) energy storage system implemented using current practice.

### SUMMARY

On a circuit between the electric grid and the site-side (below-meter) electric network an interconnection point for weatherized energy storage, combined with a disconnect switch on the grid to site circuit that, when opened, isolates the site and the energy storage below the circuit from the grid, a computing system containing metering, communications, and processing, for the grid to site circuit, and a data connection to a connected energy storage system to manage its operation in response to signals from the computing system.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic drawing illustrating a typical example of how a public utility company's power distribution system supplies two-phase power via a meter to a customer;

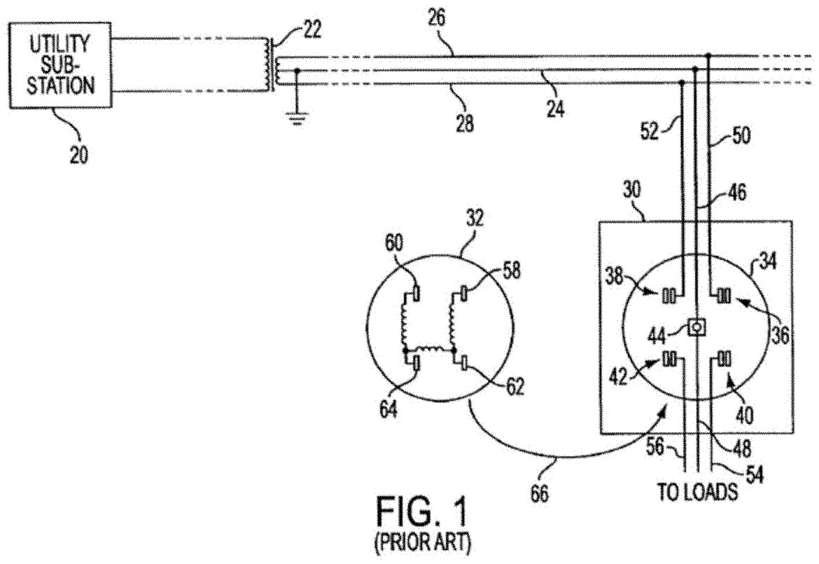

FIG. 2 shows an overview of a customer site-side energy storage system implemented using current practice.

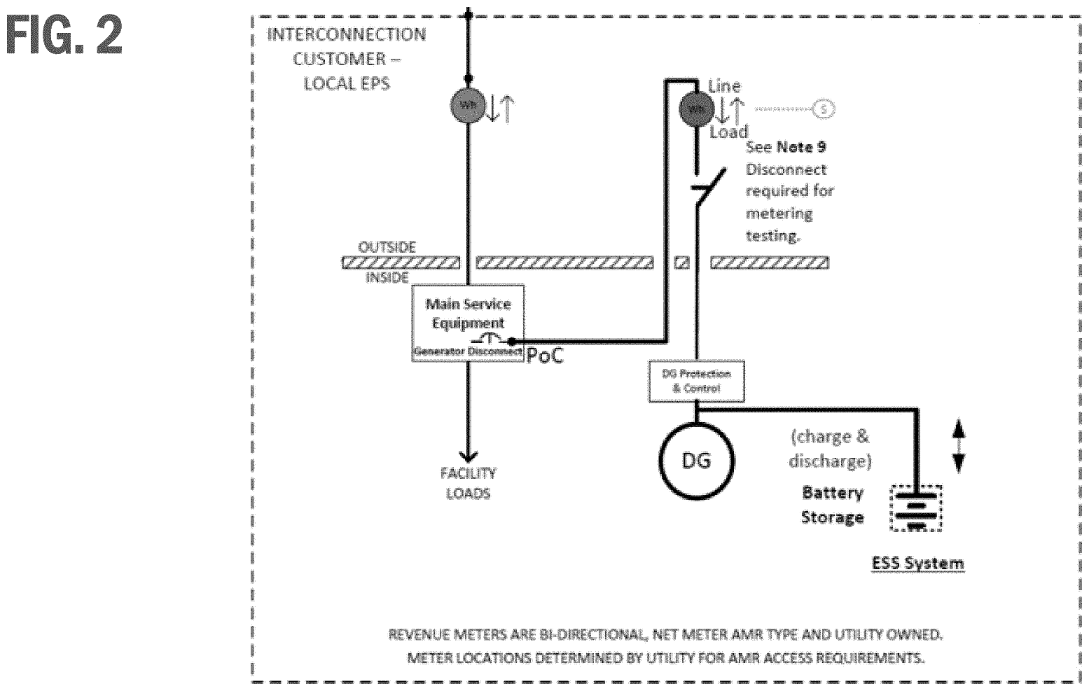

FIG. 3 shows a weatherized energy storage system interconnected at a site with electrical loads, on a grid-side (above the meter) circuit interconnection point, with a metering, communications, and grid circuit disconnect in the shut position, enabling flow of power between the grid, the site, and the energy storage system.

FIG. 4 shows a weatherized energy storage system interconnected at a site with electrical loads, on a grid-side (above the meter) circuit interconnection point, with a metering, communications, and grid circuit disconnect in the open position, enabling flow of power between the site, and the energy storage system while isolating it electrically from the grid.

### DETAILED DESCRIPTION

In the following detailed description, reference is made to the accompanying drawings, which form a part of the description. The example embodiments described in the detailed description, drawings, and claims are not intended to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

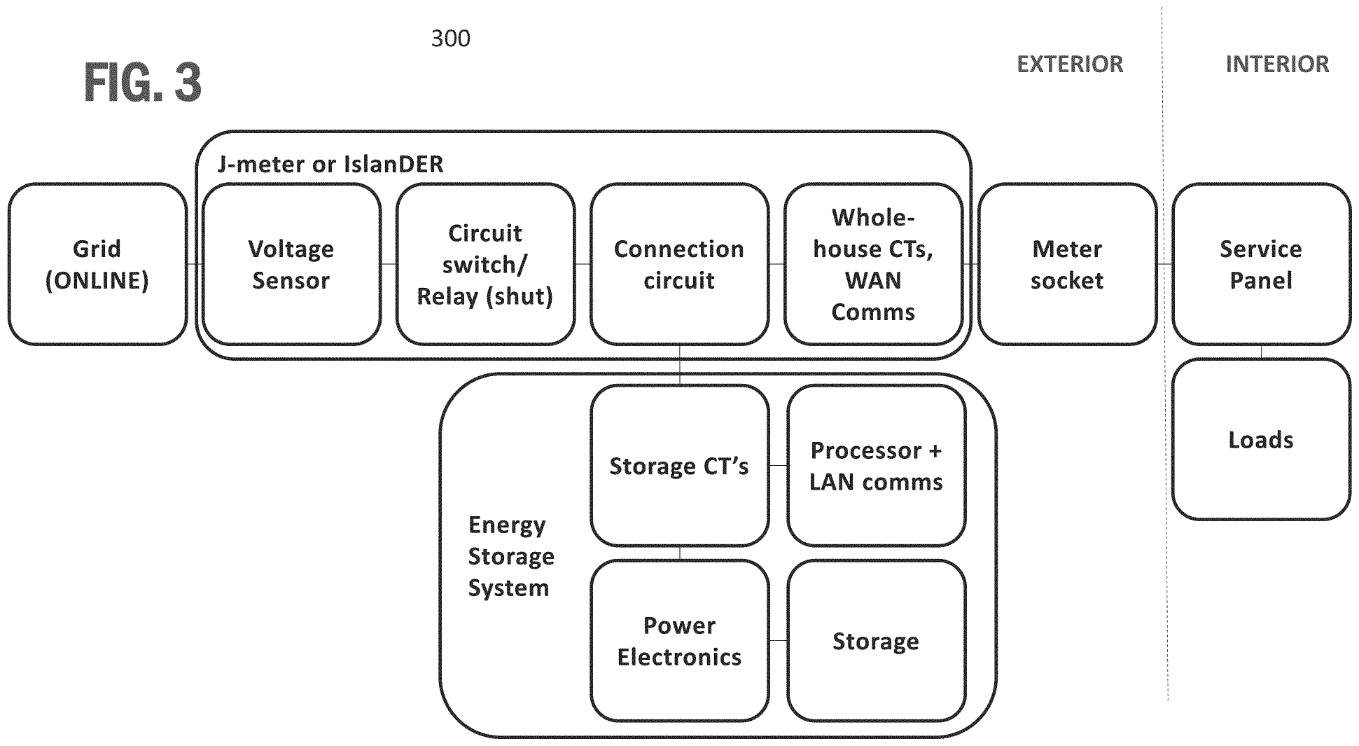

FIG. 3 shows a weatherized energy storage system interconnected at a site with electrical loads, on a grid-side (above the meter) circuit interconnection point, with a metering, communications, and grid circuit disconnect in the shut position, enabling flow of power between the grid, the site, and the energy storage system.

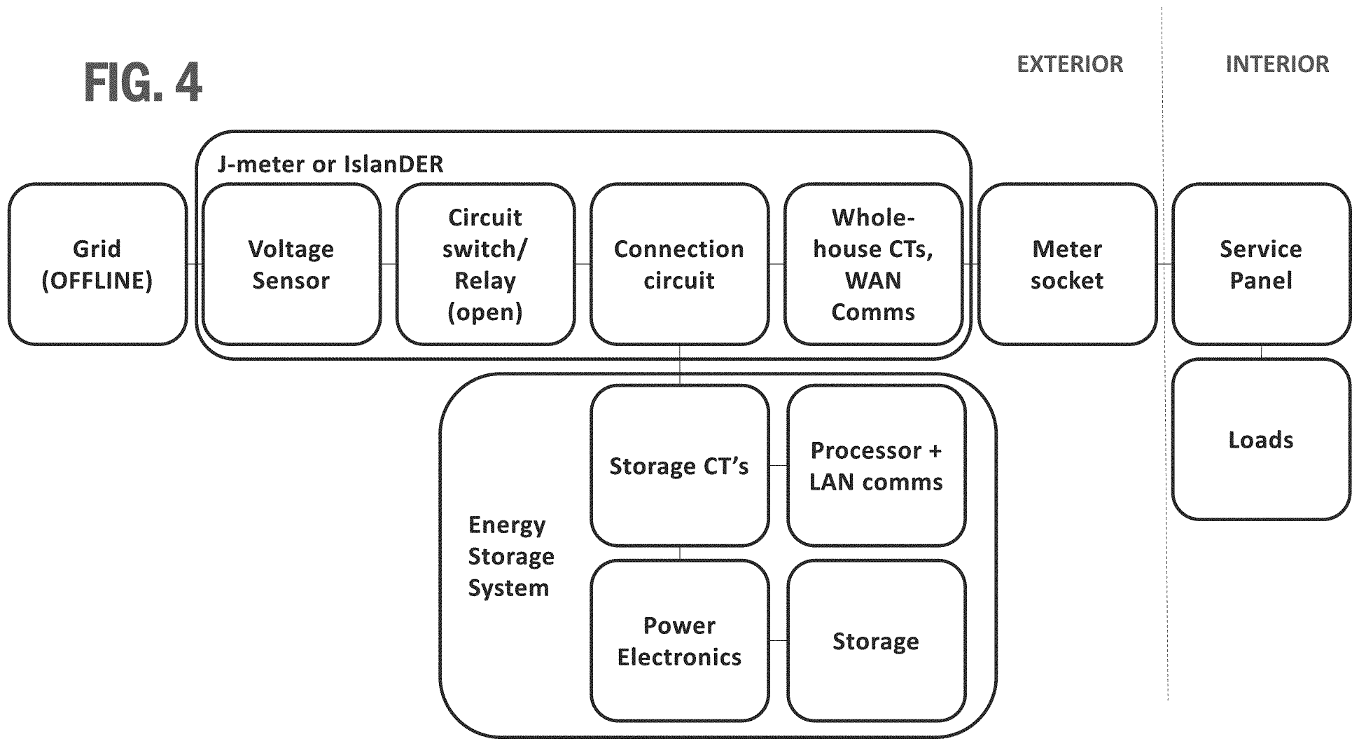

FIG. 4 shows a weatherized energy storage system interconnected at a site with electrical loads, on a grid-side (above the meter) circuit interconnection point, with a metering, communications, and grid circuit disconnect in the open position, enabling flow of power between the site, and the energy storage system while isolating it electrically from the grid.

As depicted, configuration 300 shows a complete battery storage system 300 that includes a weatherized batter and power electronics housing, a meter adapter or meter connected by a pluggable interface. Batteries, power electronics for control, current sensing, local area communications, and utility communications are provided in the battery housing.

Utility communications may be facilitated by cellular or advanced metering infrastructure for communications.

A utility meter or meter collar adapter includes grid voltage sensing, line-side disconnection, a connection for plug terminals, and current sensing for the entire facility.

Control software for batter power with multiple settings includes grid support, islanded home back up, and electric vehicle support. The support for the electric vehicles may be a stand-alone component or integrated therein.

An onboard computing platform may be utilized to make local autonomous decisions regarding best modes of operation, due to specific site requirements and/or connection to the grid, either in isolation or in coordination with other systems. Thus, a learning algorithm may be implemented to increase efficiency of the operational decision-making.

We claim:

1. On a circuit between the electric grid and the site-side (below-meter) electric network an interconnection point for weatherized energy storage, combined with a disconnect switch on the grid to site circuit that, when opened, isolates the site and the energy storage below the circuit from the grid, a computing system containing metering, communications, and processing, for the grid to site circuit, and a data connection to a connected energy storage system to manage its operation in response to signals from the computing system.
